(19) United States
(12) Patent Application Publication
(10) Pub. No.: US 2025/0072102 A1
(43) Pub. Date: Feb. 27, 2025

(54) ISOLATION OF A POWER HEMT FROM OTHER CIRCUITS

(71) Applicant: Cambridge GaN Devices Limited, Cambridge (GB)

(72) Inventors: Loizos EFTHYMIOU, Cambridge (GB); Florin UDREA, Cambridge (GB); Martin ARNOLD, Cambridge (GB)

(21) Appl. No.: 18/453,601

(22) Filed: Aug. 22, 2023

(51) Int. Cl. H01L 27/06; H01L 21/76; H01L 21/8252

(52) U.S. Cl. CPC H01L 27/0629; H01L 21/7605; H01L 21/8252; H01L 27/0605

(57) ABSTRACT

A III-nitride semiconductor based heterojunction integrated circuit (IC), comprising a substrate; a III-nitride semiconductor region located over the substrate, wherein the III-nitride semiconductor region comprises a heterojunction comprising at least one two-dimensional carrier gas of a second conductivity type; a power device comprising: a first terminal operatively connected to the III-nitride semiconductor region; a second terminal operatively connected to the III-nitride semiconductor region and laterally spaced from the first terminal; a gate structure located above the III-nitride semiconductor region and laterally spaced between the first and second terminals; and a control gate terminal operatively connected to the gate structure, wherein the control gate terminal is configured such that a potential applied to the control gate terminal modulates and controls a current flow through the two-dimensional carrier gas between the first and second terminals.

### FIELD OF THE DISCLOSURE

The present disclosure relates to III-nitride semiconductor based heterojunction devices and methods of forming the same. Particularly, but not exclusively, the disclosure relates to device isolation in a III-nitride semiconductor based heterojunction integrated circuit.

### BACKGROUND OF THE DISCLOSURE

Gallium Nitride (GaN) is a wide band gap material with properties that make it a suitable candidate for use in several fields of application (e.g. radio-frequency electronics, opto-electronics, power electronics), particularly for fields which require solid-state devices.

GaN technology allows transistors with high electron mobility and high saturation velocity to be designed. These properties of GaN have made it a good candidate for high-power and high-temperature microwave applications, for example radar and cellular communications systems. Additionally, GaN, with its wide bandgap, offers the potential for emitting light at higher frequencies, for example the green, blue, violet, and ultraviolet portions of the electromagnetic spectrum.

GaN has been more recently considered as a very promising material for use in the field of power devices. The application areas range from portable consumer electronics, solar power inverters, electric vehicles, and power supplies. The wide band gap of the material (Eg=3.39 eV) results in high critical electric field (Ec=3.3 MV/cm) which can lead to the design of devices with a shorter drift region, and therefore lower on-state resistance if compared to a silicon-based device with the same breakdown voltage.

The use of an Aluminium Gallium Nitride (AlGaN)/GaN heterostructure also allows the formation of a two-dimensional electron gas (2DEG) at the hetero-interface where carriers can reach very high mobility (μ=2000 cm²/(Vs)) values. In addition, the piezopolarization charge present at the AlGaN/GaN heterostructure, results in a high electron density in the 2DEG layer (e.g. 1×10¹³ cm⁻²). These properties allow the development of High Electron Mobility Transistors (HEMTs) and Schottky barrier diodes with very competitive performance parameters. One common parameter used to compare power semiconductor transistors is Specific ON-state resistance or Specific Rds(ON). Where specific Rds(ON) is often the product of the resistance of a device times the area of the device on wafer. An extensive amount of research has focused on the development of power devices using AlGaN/GaN heterostructures.

Layers which constitute the AlGaN/GaN heterojunction transistor are often epitaxially grown on a substrate from a different material for example Silicon (Si), Silicon Carbide (SiC) or Sapphire. Epitaxial growth of GaN on different substrates has advantages and disadvantages both in terms of the complexity and cost of growing high quality layers and in terms of device performance. A non-exhaustive list of things to consider when choosing a suitable substrate is: substrate lattice constant mismatch with GaN, substrate thermal expansion coefficient mismatch with GaN, substrate cost, substrate thermal conductivity etc.

Silicon is a popular option due to the low cost and availability of Silicon substrates. Use of Silicon as a substrate however comes with some disadvantages. Silicon and GaN have a large lattice constant mismatch and a large thermal coefficient mismatch. A transition layer is used to facilitate the growth of high quality GaN epitaxial layers on Silicon. A transition layer often comprises graded AIN/AlGaN layers or a ‘superlattice’. A GaN buffer layer is grown on the transition layer. The GaN buffer layer is often carbon doped to limit vertical leakage from the surface high voltage terminal e.g. drain and the substrate back-end contact. An unintentionally doped GaN layer is then grown where the two dimensional electron gas at the interface with an AlGaN barrier layer is present.

The 2DEG which inherently exists at the AlGaN/GaN hetero-interface has been found to be unstable and lose electron charge under a prior high voltage stress. This phenomenon is, known as dynamic Ron or current collapse. When the device is under high voltage stress in the off-state (a high potential voltage is present on the high voltage drain terminal with respect to the source terminal and the gate voltage is at a potential below the threshold voltage to ensure that the device is off), part of the electrons in the 2DEG are lost by trapping mechanisms in either traps in the bulk of the GaN, the transition layer (i.e. the layer placed between the substrate and the GaN buffer) or at the surface of the device. Hot carrier injection in the passivation layer, next to the gate (the control terminal) also may play a role, though this is not believed to be the major contribution to the dynamic Ron phenomenon. This loss of charge from the 2DEG layer to the surrounding traps leads to a subsequent decrease in the conductivity during on-state and thus an increase in the on-state resistance. The effect could be seen also during the switching or when the device is in operation in a real system.

One way to alleviate the increase in the on-state resistance is to inject holes during the off-state or during the on-state operation to passivate the bulk or surface traps and prevent or slow down the trapping of electrons in the vicinity of the 2DEG layer (either in the bulk or at the surface).

There are several theories describing the effect of the injected holes. One possible mechanism is that the injected holes change the electric field distribution from the 2DEG to the substrate, by moving the high fields away from the 2DEG vicinity, towards the substrate. As a result the move the depletion region and the high electric field away from the 2DEG's vicinity and 2DEG is exposed to lower electric fields which slows down the mechanism of electron trapping in the vicinity of the 2DEG therefore prevents the depletion of the 2DEG in the off-state as shown by D. Pagano et al in [“Suppression of substrate coupling in GaN high electron mobility transistors (HEMTs) by hole injection from the p-GaN gate”, Appl. Phys. Lett. 115, 203502 (2019), https://doi.org/10.1063/1.5121637]. Note that in the presence of injected holes, the 2DEG still depletes at high voltages during off-state and at very high voltages (closer to nominal breakdown) the whole of the 2DEG is depleted, but the peak of the electric field is moved away from the 2DEG towards the substrate.

IKOSHI et al., US 2011/0215379 A1 patent application describes a p-type injector placed at the surface of the semiconductor which is connected to a hole injector electrode having virtually the same potential as that of the drain. The patent describes embodiments where the hole injector is connected via metallization to the drain electrode. Other embodiments, all based on a hardwired injection electrode placed on a p-type injector region, describe placing the p-injector region inside the drift region, between the gate and the high voltage terminal (drain), or outside the drift region, in the close proximity of the high voltage terminal (drain).

KINZER et al., US 2019/0326427 A1 patent application describes a p-type injector placed between the gate and the drain terminals, which is not in direct electrical contact to the drain electrode but capacitively connected to it. The p-injector can inject holes via displacement currents flowing through the dielectric layer (acting as the dielectric of a capacitor). The device injects holes only during the transient, but not under steady-state during the on-state or off-state conditions. The amount of injection is also limited by the transient dV/dt current and the capacitance of the dielectric layer.

[K. J. Chen et al., “GaN-on-Si Power Technology: Devices and Applications,” in IEEE Transactions on Electron Devices, vol. 64, no. 3, pp. 779-795, March 2017.] and [M. J. Uren et al., “Leaky Dielectric” Model for the Suppression of Dynamic Ron in Carbon-Doped AlGaN/GaN HEMTs,” in IEEE Transactions on Electron Devices, vol. 64, no. 7, pp. 2826-2834 July 2017.] provide further background information regarding this technological field.

In power electronics, it is sometimes desirable for protection and sensing circuitry (such as current sensing, over-voltage protection, temperature sensing) to be integrated with the main (often enhancement mode) power switch. Monolithic integration of such functionality, rather than a discrete implementation, allows a reduction in the overall system size and/or costs, e.g. due to a reduction in the bill of material, and often results in improved performance through the reduction of parasitic components associated with the interconnections between discrete devices.

A lateral technology, for example GaN-on-Si, allows for integration of additional circuits to be integrated on the same chip as a main GaN power HEMT. The additional circuits may also comprise devices with a two dimensional electron gas, for example low voltage transistors or resistors. As additional circuits tend to operate at low voltages (e.g. 12V rating for a low voltage HEMT) compared a power device, they are less likely or unlikely to experience Dynamic Ron effect following a period of OFF-state stress (where OFF-state here refers to the mode of operation of the low voltage HEMT not the power HEMT) compared to a GaN power HEMT.

A power device (such as a GaN power HEMT), with additional integrated circuits may often be described as a power integrated circuit (power IC). For the reliable operation of a GaN power IC, it is generally desirable that the operation of the GaN power HEMT does not affect, or affects as little as possible, the operation of the additional circuits included on chip. For example, when the GaN power HEMT is in the ‘OFF’-state mode of operation, and therefore a high potential is present across its terminals, the additional circuits may be effectively isolated from the high potential. Moreover, it is generally desirable that cross talk or coupling between the GaN power HEMT and the additional circuits should be minimised or eliminated when the GaN power HEMT device is switching.

Isolation between the power HEMT and additional circuitry may be achieved, for example, by defining distinctive active areas for the power HEMT and other on-chip devices. The active area may be defined as the region where conduction occurs via the 2DEG when a device is in the ON-state mode of operation. The active areas of the various devices may be made distinct from one another through the removal of the two dimensional electron gas in regions between the active area of devices. The 2DEG in sections of the chip may be removed, for example, through fluorine plasma ion implantation or through etching of the AlGaN barrier or AlGaN/GaN heterojunction where the 2DEG is formed.

Effective isolation may be more challenging during switching where capacitive coupling may occur. Shielding methods may be used to minimize capacitive coupling.

Effective isolation may also be more challenging following a period of OFF-state stress for the power HEMT, where buffer charging may occur due to the high potential across the terminals of the device and in particular between the drain terminal and the substrate (which is often at source potential). Buffer charging is more likely in the active area of the power HEMT and in particular the drift region of the power HEMT. However, the Applicants have discovered that, if buffer charging occurs (e.g. non equilibrium charges in the Carbon doped region as a consequence of the high potential in the power HEMT) in the region under the additional circuits, it may cause problems in the operation of these circuits which may be more sensitive to variations of their parameters than the power HEMT.

For these reasons and more, the Applicant has recognised a need for improved isolation in semiconductor devices.

### SUMMARY

It is generally desirable for reliable operation of a power integrated circuit (IC) that the effect of Dynamic Rdson, which affects the 2DEG conductivity of the power HEMT following a period of OFF-state stress, does not affect the 2DEG conductivity or threshold of components in additional on-chip circuits. Existing isolation techniques may be ineffective in preventing buffer charging as they are generally targeted at the isolation of the 2DEG in separate active areas or capacitive coupling. Negative buffer charging (i.e. non-equilibrium negative charges) may in particular be a challenge for existing techniques. This negative charge may, for example, be trapped in acceptor traps in the Carbon-doped buffer and may require a hole current to rebalance the charge. However, in general previous hole injection approaches have focused on hole injection in the active area of the power HEMT.

Broadly speaking therefore, it is an object of the present invention to provide a structure which achieves a more effective isolation of additional circuits in a GaN power IC, such that they are less (or not at all) affected by the Dynamic Ron experienced by the (e.g. GaN) power HEMT in the power IC.

According to a first aspect of the invention, there is provided a III-nitride semiconductor based heterojunction integrated circuit (IC), comprising:
a substrate;
a III-nitride semiconductor region located over the substrate, wherein the III-nitride semiconductor region comprises a heterojunction comprising at least one two-dimensional carrier gas of a second conductivity type;
a power device comprising:
   a first terminal operatively connected to the III-nitride semiconductor region;
   a second terminal operatively connected to the III-nitride semiconductor region and laterally spaced from the first terminal;
   a gate structure located above the III-nitride semiconductor region and laterally spaced between the first and second terminals; and
   a control gate terminal operatively connected to the gate structure, wherein the control gate terminal is configured such that a potential applied to the control gate terminal modulates and controls a current flow through the two-dimensional carrier gas between the first and second terminals;
a second device comprising at least one second two-dimensional carrier gas of the second conductivity type;
an isolation region between the power device and the second device such that the two dimensional carrier gas of the power device and the second two dimensional carrier gas of the second device are separated by the isolation region to form two distinctive active areas of two dimensional carrier gas; and
at least one region of a first conductivity type positioned laterally between an active area of the power device and an active area of the second device, wherein a Schottky or ohmic metal contact is formed on the at least one region of the first conductivity type.

The at least one region of the first conductivity type may be a carrier injector configured to inject carriers of the first conductivity type into the III-nitride semiconductor region.

Thus, according to a second aspect of the invention, there is provided a III-nitride semiconductor based heterojunction integrated circuit (IC), comprising:
a substrate;
a III-nitride semiconductor region located over the substrate, wherein the III-nitride semiconductor region comprises a heterojunction comprising at least one two-dimensional carrier gas of a second conductivity type;
a power device comprising:
   a first terminal operatively connected to the III-nitride semiconductor region;
   a second terminal operatively connected to the III-nitride semiconductor region and laterally spaced from the first terminal;
   a gate structure located above the III-nitride semiconductor region and laterally spaced between the first and second terminals; and
   a control gate terminal operatively connected to the gate structure, wherein the control gate terminal is configured such that a potential applied to the control gate terminal modulates and controls a current flow through the two-dimensional carrier gas between the first and second terminals;
a second device comprising at least one second two-dimensional carrier gas of the second conductivity type;
an isolation region between the power device and the second device such that the two dimensional carrier gas of the power device and the second two dimensional carrier gas of the second device are separated by the isolation region to form two distinctive active areas of two dimensional carrier gas; and
a carrier injector configured to inject carriers of the first conductivity type into the III-nitride semiconductor region, wherein a Schottky or ohmic metal contact is formed on the carrier injector.

Implementations of the present invention may provide more effective isolation of additional circuits on a GaN power IC. More specifically this solution may improve isolation from buffer charging which may occur during/following a period of OFF-state stress in the power HEMT. This may be facilitated, for example, by the placement of a hole injection structure in the region between the power HEMT and the additional circuits.

In the first aspect of the invention, the region of first conductivity type may provide isolation by facilitating a shaping of the potential during OFF-state operation. This is possible due to the formation of a junction and therefore the formation of a depletion region between the drain terminal of the power device (for example a GaN HEMT) and the region of a first conductivity type (for example a pGaN region), where the potential applied to the drain terminal of the power device is dropped in the depletion region and does not reach the region under the at least one additional device.

It may be suitable for the region of a first conductivity type (which may be structurally the same or similar to the region referred to as the injector of carriers of the second aspect) to be biased at a low potential (e.g. below 10% of the drain potential of the power HEMT) or at source potential of the power HEMT.

In the second aspect of the invention, an injector of carriers of the first conductivity type is provided between the power device active area and the at least one additional device active area. In some examples the injection of carriers may be more effective (i.e. may inject a greater number of carriers) if the injector of carriers is biased at a positive potential (compared to the source terminal of the power device). Nonetheless, a region of a first conductivity type (for example a pGaN region) may be effective in providing isolation of the one additional device with a two dimensional carrier gas (for example a 2DEG resistor) without the injection of holes but rather through the shaping of the potential such that a high potential from the drain terminal during OFF-state operation of the power device does not reach the region under the at least one additional device. The injector of carriers may also be referred to as a hole injector, p-injector region or p-injector of holes.

The examples presented below are generally applicable to both aspects of the invention.

Thus, we herein describe a III-nitride semiconductor based heterojunction integrated circuit, comprising:
a substrate;
a III-nitride semiconductor region located over the substrate, wherein the III-nitride semiconductor region comprises a heterojunction comprising at least one two-dimensional carrier gas;
a power device which comprises at least:
a first terminal operatively connected to the III-nitride semiconductor region;
a second terminal operatively connected to the III-nitride semiconductor region and laterally spaced from the first terminal;
a gate structure located above the III-nitride semiconductor region and laterally spaced between the first and second terminals;
a control gate terminal operatively connected to the gate structure, wherein a potential applied to the control gate terminal modulates and controls a current flow through the two-dimensional carrier gas between the first and second terminals, the at least one two-dimensional carrier gas being a second conductivity type;
at least one additional device (e.g. transistor, diode, resistor, capacitor) which comprises at least one two-dimensional carrier gas of a second conductivity type;
an isolation region between the power device and the at least one additional device such that the two dimensional carrier gas of the power device and the two dimensional carrier gas of the at least one additional device are not one continuous region of two dimensional carrier gas but rather two distinctive active areas of two dimensional carrier gas;
at least one injector of carriers of the first conductivity type placed between the power device active area and the at least one additional device active area;

In examples, the power device may be a high electron mobility transistor (HEMT). Similarly, one or more of the at least one two-dimensional carrier gas may be a two-dimensional electron gas (2DEG), the first terminal may be the source terminal, and the second terminal may be the drain terminal. One or more of the at least one regions of the first conductivity type may be a hole injector, also known as a p-injector of holes. The 2DEG is formed at the interface of the heterojunction. The interface may comprise, for example, the interface of two layers such as GaN and AlGaN. Other heterojunction layers comprising at least two materials with different bandgaps are also possible.

The at least one region of the first conductivity type may be formed of any suitable III-Nitride layer such as a Gallium Nitride (GaN) material or an Aluminium Gallium Nitride (AlGaN) material. In embodiments where the at least one region of the first conductivity type is a p-injector, the p-type dopant may be, for example, Magnesium, but it will be understood that other p-type dopants may be utilized in addition to or instead of a Magnesium p-type dopant. The p-injector could be formed within one of the existing layer as part of the existing heterojunction (GaN or AlGaN) by doping with p-dopant a particular region of that layer, or could be grown or regrown or formed by deposition as an additional III-nitride layer. The p-injector could be for example made of a p-type doped GaN material grown selectively on top of the AlGaN layer.

The gate structure of the power device may be formed by a p-type region (recessed or non-recessed, grown or regrown) and connected to the gate terminal through an ohmic or Schottky metallization. Advantageously, in this embodiment a normally-off HEMT may be realized with a positive threshold voltage. The p-type dopant may be, for example, Magnesium, but the it will be understood that other p-type dopants may be utilized in addition to or instead of a Magnesium p-type dopant.

The gate structure of the power device may alternatively be made or formed of a recessed or non-recessed insulating layer above which the gate terminal is placed to form a MISFET (Metal Insulating FET). The MISFET may be a normally-off or normally-on transistor.

Alternatively, the gate structure of the power device could be made of a Schottky metal directly placed on the III-Nitride region. In this case a normally-on transistor (also known as a depletion mode transistor) may be formed with a negative threshold voltage.

An electrical contact through ohmic or Schottky metallization may also be formed on the at least one region of the first conductivity type.

The electrical contact (e.g. the Schottky or Ohmic contact) formed on the at least one region of the first conductivity type may be similar in nature to an electrical contact made by the gate control terminal to the gate structure. Such contacts may be formed or established in the same process step and using the same mask as that for the gate structure.

The terminal formed by or connected to a contact on the at least one region of the first conductivity type may be connected at ground potential. Alternatively, it may be connected to a fixed potential. The fixed potential may be applied externally to the power IC or may be a voltage level generated internally on the power IC using an additional on-chip circuit like for example a voltage regulator.

The fixed potential may be a regulated voltage VDD which is also used to power the controller or gate driver in a power electronics circuit where the power IC is used.

The fixed potential may be a rail voltage, for example the input DC rail of the switch mode power supply where the power IC is used. The terminal may be connected to only a fraction of the rail potential through the use of a potential divider connected between the DC rail and ground.

Alternatively, the terminal on the at least one region of the first conductivity type may be connected to a switching node such as the control signal to the power IC.

In another example the at least one region of the first conductivity type may be connected to drain potential. The terminal may be connected to only a fraction of the drain voltage potential through the use of a potential divider connected between the drain and ground.

A high voltage potential (e.g. between 10% and 100% of the drain potential during off-state operation of the power HEMT) bias of the at least one region of the first conductivity type may enable a hole current during the OFF-state operation of the power HEMT (as well as the ON-state). This may prevent the trapping of negative charges in the GaN buffer below the additional on-chip components.

A low voltage potential (e.g. below 10% of the drain potential during off-state operation of the power HEMT) may enable a hole current during the ON-state operation of the power HEMT. This may enable the fast de-trapping of negative charges in the GaN buffer below the additional on-chip components, depending on the placement of the at least one region of the first conductivity type.

In one example, the isolation region may comprise a region of implantation of negatively charged fluorine ions to significantly reduce or make negligible the conductivity of the 2DEG in that region.

In another example, the isolation region may be achieved through the etching of the AlGaN barrier layer resulting in an AlGaN mesa structure. The recess through etching may reach the GaN channel layer.

By being operatively connected to the III-nitride region, the first terminal and the second terminal make an electrical contact to the 2DEG layer or portions of the 2DEG. The contacts of the first terminal and the second terminal to the 2DEG may be ohmic contacts.

In one example, a shielding structure may also be present in the region between the active area of the at least one additional circuit and the power HEMT. The shielding structure may comprise an ohmic contact made in the same process step as the ohmic contact of the first and second terminal.

In another example, the at least one region of the first conductivity type may be formed on a totally or partially recessed AlGaN barrier.

In another example, the at least one region of the first conductivity type may be formed on a trench formed in the GaN layer.

In some examples, more than one at least one region of the first conductivity type may be formed.

In some examples, more than one shielding region may be formed.

According to a third aspect of the invention, there is provided a method of forming an III-nitride semiconductor based heterojunction integrated circuit (IC), comprising:
forming a substrate;
forming a III-nitride semiconductor region over the substrate, wherein the III-nitride semiconductor region comprises a heterojunction comprising at least one two-dimensional carrier gas of a second conductivity type;
forming a power device on the III-nitride semiconductor region, the power device comprising:
a first terminal operatively connected to the III-nitride semiconductor region;
a second terminal operatively connected to the III-nitride semiconductor region and laterally spaced from the first terminal;
a gate structure located above the III-nitride semiconductor region and laterally spaced between the first and second terminals; and
a control gate terminal operatively connected to the gate structure, wherein the control gate terminal is configured such that a potential applied to the control gate terminal modulates and controls a current flow through the two-dimensional carrier gas between the first and second terminals;
forming a second device on the III-nitride semiconductor region, the second device comprising at least one second two-dimensional carrier gas of the second conductivity type;
forming an isolation region between the power device and the second device such that the two dimensional carrier gas of the power device and the second two dimensional carrier gas of the second device are separated by the isolation region to form two distinctive active areas of two dimensional carrier gas;
forming at least one region of a first conductivity type positioned laterally between an active area of the power device and an active area of the second device; and
forming a Schottky or ohmic metal contact on the at least one region of the first conductivity type.

The gate structure may be made or formed in the same process step as the region of a first conductivity type. Alternatively, they may be formed in separate process steps. In embodiments with a plurality of gate structures and/or a plurality of regions of a first conductivity type, any or all of these regions may be formed in the same or separate process steps.

### BRIEF DESCRIPTION OF THE DRAWINGS

The present disclosure will be understood more fully from the accompanying drawings, which however, should not be taken to limit the disclosure to the specific embodiments shown, but are provided for aiding in explanation and understanding only.

FIG. 1 depicts a cross sectional schematic of an example AlGaN/GaN HEMT device.

FIG. 2 depicts a cross sectional schematic of an example GaN region of an AlGaN/GaN HEMT device.

FIG. 3 depicts a cross sectional schematic of an example AlGaN/GaN HEMT integrated circuit.

FIG. 4 depicts a cross sectional schematic of a further example AlGaN/GaN HEMT integrated circuit.

FIG. 5 depicts negative trapped charges in an example AlGaN/GaN HEMT integrated circuit.

FIG. 6 depicts example high voltage equipotential lines in a AlGaN/GaN HEMT integrated circuit.

FIG. 7 depicts negative trapped charges in an example AlGaN/GaN HEMT integrated circuit.

FIG. 8 depicts a cross sectional schematic of an example AlGaN/GaN HEMT integrated circuit according to the present disclosure.

FIG. 9 depicts a cross sectional schematic of a further example AlGaN/GaN HEMT integrated circuit according to the present disclosure.

FIG. 10 depicts a cross sectional schematic of a further example AlGaN/GaN HEMT integrated circuit according to the present disclosure.

FIG. 11 depicts a cross sectional schematic of a further example AlGaN/GaN HEMT integrated circuit according to the present disclosure.

FIG. 12 depicts a cross sectional schematic of a further example AlGaN/GaN HEMT integrated circuit according to the present disclosure.

FIG. 13 depicts example high voltage equipotential lines in a AlGaN/GaN HEMT integrated circuit.

FIG. 14 depicts a top view schematic of an example AlGaN/GaN HEMT integrated circuit.

FIG. 15 depicts a top view schematic of a further example AlGaN/GaN HEMT integrated circuit.

FIG. 16 depicts a top view schematic of an example AlGaN/GaN HEMT integrated circuit according to the present disclosure.

FIG. 17 depicts a flow diagram of an example method of forming a AlGaN/GaN HEMT integrated circuit according to the present disclosure.

### DETAILED DESCRIPTION OF THE PREFERRED EMBODIMENTS

Like reference numerals are provided for corresponding features depicted in the accompanying drawings.

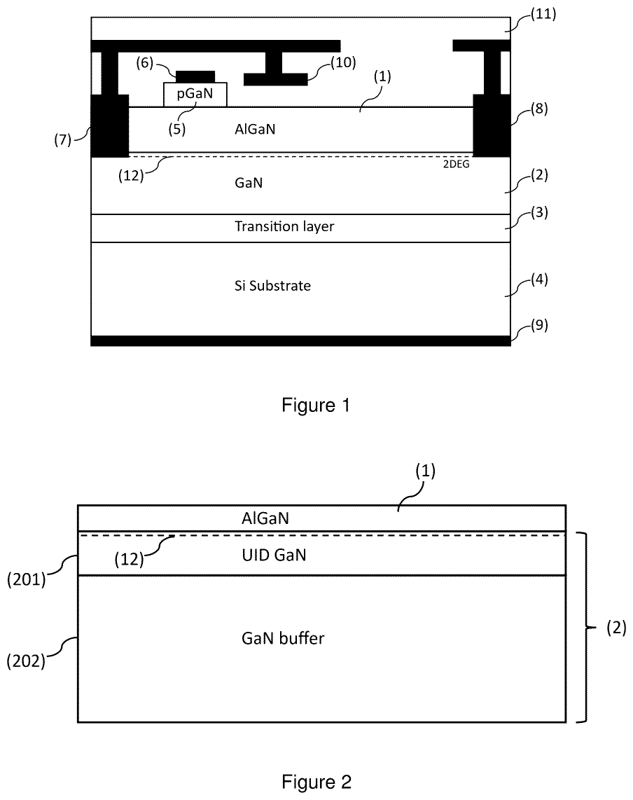

FIG. 1 illustrates an example cross section of an example AlGaN/GaN HEMT device. It will be understood that the substrate (4) may be formed from various materials in place of Si, such as Silicon Carbide (SiC) and/or sapphire.

The HEMT comprises an AlGaN/GaN heterojunction between the GaN layer (2) and the AlGaN layer (1), where a two-dimensional electron gas (2DEG) (12) is formed. The AlGaN/GaN heterojunction layers (1, 2) are grown epitaxially on the substrate (4). A transition layer (3) is present between the AlGaN/GaN heterojunction layers (1, 2) and the substrate. The device may comprise a substrate back metallisation contact (9).

The device in FIG. 1 further comprises a highly p-doped GaN region (5) which depletes the 2DEG (12) under it at zero bias conditions, to create an enhancement mode transistor. A gate contact (6) is placed on the p-GaN region (5). A Schottky or ohmic contact may be formed on the p-GaN region. In other examples, different gate technologies may be used.

The 2DEG (12) is contacted by a source contact (7) and a drain contact (8). In the example device of FIG. 1, the contacts (7, 8) to the 2DEG (12) are made by recessing the AlGaN layer (1). However, other methods of forming ohmic contacts may be used.

The substrate (4) may be connected to the source contact (7) potential. This may be done at package level, printed circuit board (PCB) level, or device level. This connection is not illustrated in FIG. 1 or in other examples illustrated herein, for clarity in the illustration.

Power HEMTs such as that depicted in FIG. 1 (and in power devices in general) may include field plate structures to shape the potential distribution during OFF-state bias conditions. A metal field plate structure (10) is illustrated as an example in FIG. 1. The device further comprises surface passivation of the semiconductor layers and additional intermetal dielectric layers. For clarity in the illustration, these layers are depicted as a single region (11).

FIG. 2 illustrates an example of a cross section of the GaN region (2), showing its sub-division into two further (sub-)regions; a GaN buffer (202) and an unintentionally doped (UID) GaN region (201). The GaN buffer (202) may be thicker than the UID GaN region (201). For example, the GaN buffer (202) may have a thickness of 2-4 um (e.g. for a 650V rated device and be substantially doped, whereas the UID GaN region (201) may have a thickness of 0.1-0.4 um. It will be understood that the thickness of these regions may vary depending on the intended functionality or power rating of the device. For example, in embodiments of the invention illustrated in the figures below, the GaN buffer layer (202) may be substantially thinner, or not present at all. The GaN buffer layer (202) may be carbon doped.

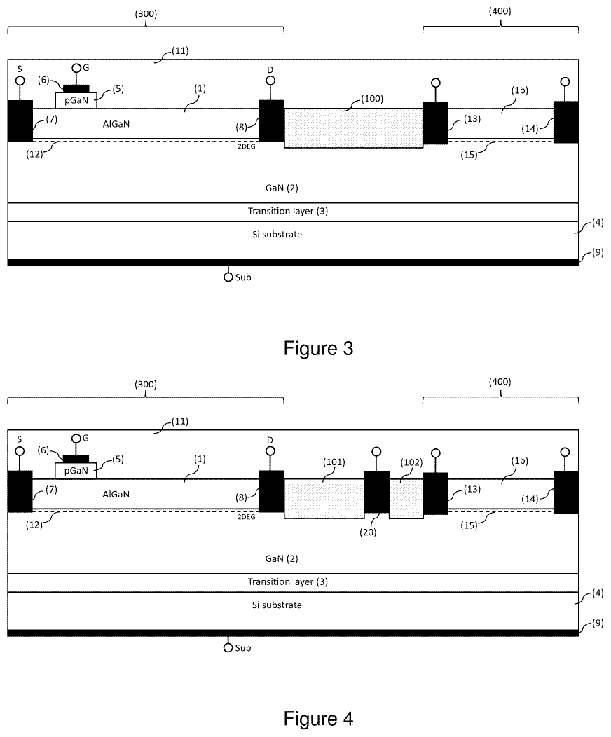

FIG. 3 illustrates an example device in which a power HEMT (300) is separated from a low voltage component (400) (also referred to as an additional device or additional component in other sections), for example a 2DEG resistor comprising low voltage contacts (13, 14), by an isolation region (100). The isolation region (100) may be formed through e.g. fluorine plasma ion implantation to severely limit the conductivity of the 2DEG which is inherently present at the interface of the AlGaN/GaN heterojunction. Alternatively, the isolation region (100) may be formed by removing the AlGaN barrier layer and optionally the top of the GaN layer (2) in order to avoid the formation of the 2DEG in that region. The isolation region (100) is generally effective in facilitating the formation of two separate 2DEG regions, region (12) for the high voltage HEMT and region (15) for the 2DEG resistor, such that they are not electrically connected. The 2DEG resistor illustrated in FIG. 3 is only an example, and other low voltage components or circuits (400) could be included on a power IC in addition or in place of the 2DEG resistor such as an enhancement mode transistor, a depletion mode transistor, a capacitor etc.

It will be understood that the accompanying illustrations are schematic illustrations, and are not to scale. In embodiments, the lateral dimension of the isolation region (100) may frequently be longer (for example about 2 times or more) than the length of the drift region of the power device. This applies equally to FIG. 3 and the other schematic illustrations herein.

FIG. 4 illustrates a further example device similar to that shown in FIG. 3. In FIG. 4, a contact (20) is formed in the isolation region (101, 102) between the power HEMT (300) and the 2DEG resistor (400). This contact (20) may assist in shielding the low voltage component (400) from the high voltage component (300). The contact (20) may be grounded or may be biased at a low voltage fixed potential (for example below 20V). The contact (20) may therefore set a known potential where it is placed and helps to ensure that, when the drain terminal of the power HEMT is at high potential, all or most of the potential is dropped between the drain terminal and the contact (20) such that high potential does not reach the low voltage component (400) laterally along the surface of the wafer (e.g. within 300 nm towards the substrate from the surface of the top semiconductor layer).

However, the approach illustrated in FIG. 4 may only be successful in ensuring that the low voltage device (400) is shielded against any potential which may reach the low voltage device laterally along the surface of the device. It may also be the case that, during OFF-state operation of the power HEMT, a high potential is present in the GaN buffer layer, and the approach illustrated in FIG. 4 may be less suitable for shielding the low voltage component (400) against this potential.

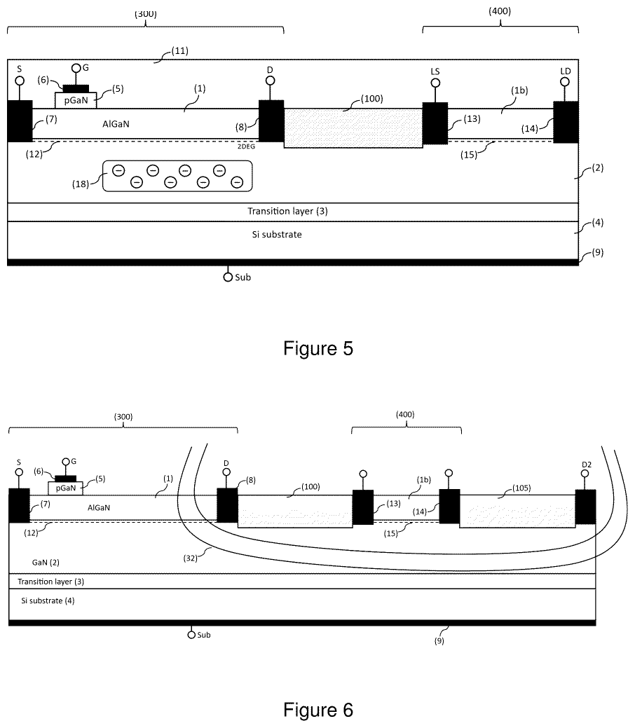

In the GaN buffer layer in the drift region of the power HEMT (i.e. between the gate and drain terminal of the power HEMT) a potential drop will be present between the high voltage drain terminal and a substrate contact (9) connected to source potential. During the OFF-state operation of the power HEMT, charges may be trapped in the GaN buffer region which may not be released immediately when the device is turned-ON. Negative trapped charges (18) are illustrated in FIG. 5. This is considered a common cause for Dynamic on state resistance (Dynamic Ron). If a similar effect occurs in the buffer region below the low voltage components of the power IC (e.g. 2DEG resistor (400)) then a Dynamic Ron effect may be observed in the low voltage component (400) as well.

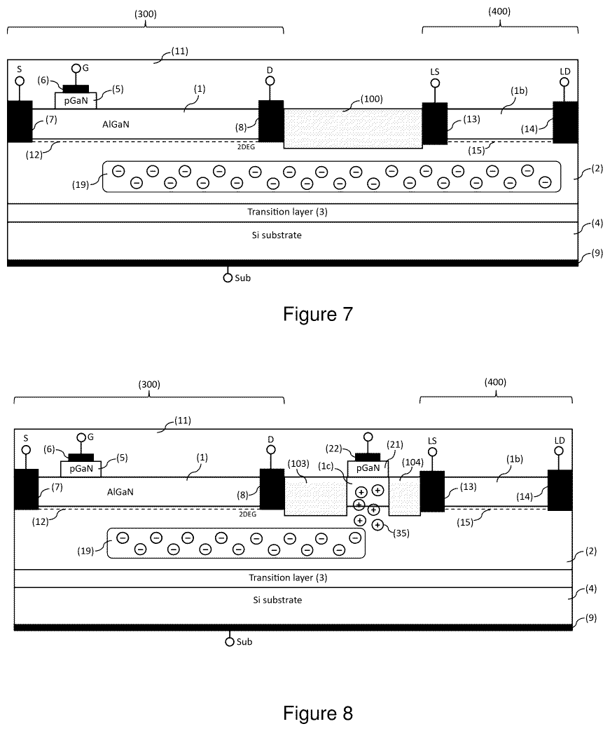

Charge trapping below the low voltage components (400) of the power IC may also occur due to the high potential applied to the drain of the power HEMT raising the potential of the GaN buffer under the low voltage components (400). This is illustrated in FIG. 6 which shows an example of high voltage equipotential lines (32) in the GaN buffer region under 2DEG resistor (400). The resulting region of negative trapped charges (19) extending to the region under the 2DEG resistor (400) is illustrated in FIG. 7. The consequences of the Dynamic Ron on the low voltage components (400) may be more significant, as the operation of the low voltage components or circuits (400) may often be more sensitive to parameter variations than the operations of the power HEMT (300).

Thus, the resistance of the 2DEG resistor (400) (or other low voltage component) may be affected during the OFF-state operation of the power HEMT due to the presence of high potential in this region (as the 2DEG resistance will likely decrease), as illustrated in FIG. 6. Additionally, the resistance of the 2DEG resistor (400) may be further affected when the power HEMT switches back to ON-state operation following a period of OFF-state operation, due to negative trapped charges as illustrated in FIG. 7 (as the 2DEG resistance will likely increase).

The isolation method in FIG. 3 and the combination of isolation and shielding in FIG. 4 may not be effective in preventing the trapping (during power HEMT OFF-state) or in enabling the fast de-trapping (during power HEMT ON-state) of negative charges in the GaN buffer below the low voltage components.

FIG. 8 illustrates a cross section schematic of an embodiment according to the present disclosure. In this embodiment, a p-GaN region (21) is provided in the isolation region (103, 104) between the power HEMT (300) and the low voltage component(s) (400), such as the example 2DEG resistor depicted in FIG. 8. The p-GaN region (21) is formed on the AlGaN layer. A contact (22) may be formed on the p-GaN region (21). The contact may be an ohmic or Schottky contact. The p-GaN region (21) and contact (22) may be formed in the same process step as the p-GaN region (5) and contact (6) of the gate of the power HEMT (300), or they may be formed in a separate process step.

The p-GaN region (21) may act as a hole injector (also referred to as p-injector of holes or p-injector in other sections) to prevent or reduce the trapping of negative charges in the GaN buffer below the low voltage components (400). Additionally or alternatively, the p-GaN region (21) may act as a hole injector to enable the fast de-trapping of negative charges in the GaN buffer below the low voltage components (400). This is because the hole current (35) from the hole injector is dependent on the mode of operation of the power HEMT (300) (for example ON-state, OFF-state etc.) and the bias of the contact (22) on the pGaN region (21).

For increased hole current (35), it may be preferable to bias the p-GaN region (21) at a positive potential. This potential may be a fixed potential or a switching potential. The fixed potential may be a regulated voltage VDD, which may also be used to power the controller or gate driver in a power electronics circuit where the power IC is used. For example, the fixed potential may be a rail voltage, for example the input DC rail of the switch mode power supply where the power IC is used. In embodiments, the terminal may be connected or connectable to only a fraction of the rail potential through the use of a potential divider connected between the DC rail and ground.

Alternatively, the terminal on the pGaN region (21) may be connected to a switching potential such as the control signal to the power IC.

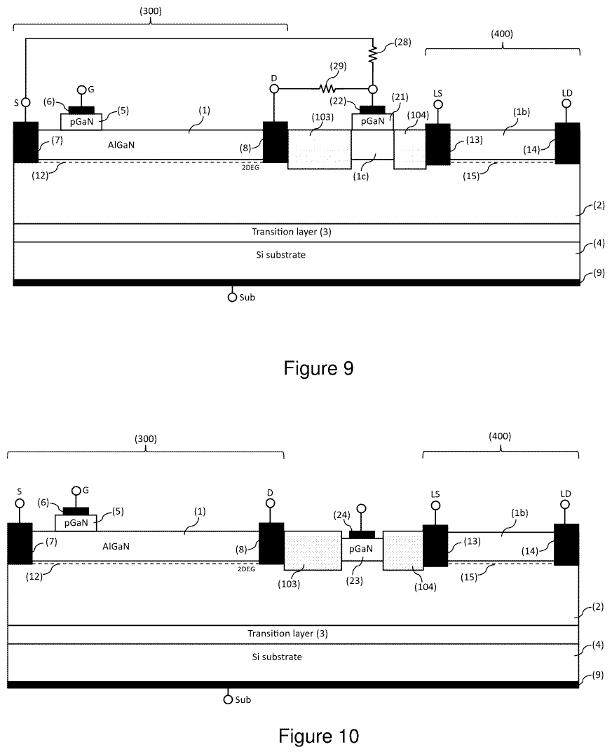

In another example the pGaN region (21) terminal may be connected to the drain potential. The terminal may be connected to only a fraction of the drain voltage potential through the use of a potential divider connected between the drain and ground. This is illustrated in FIG. 9 as an example where the potential divider is formed by resistors 28, 29. The various features of FIG. 9 otherwise correspond to that of FIG. 8.

A high voltage potential (e.g. between about 10% and about 100% of the drain potential) bias on the contact on the p-GaN region (21) may facilitate a hole current (35) during the OFF-state operation of the power HEMT (300), as well as the ON-state. This may prevent or reduce the trapping of negative charges in the GaN buffer below the low voltage components (400).

A low voltage potential (e.g. below 10% of the drain potential) may facilitate a hole current (35) during the ON-state operation of the power HEMT (300). This may facilitate the fast de-trapping of negative charges in the GaN buffer below the low voltage components.

In implementations, the bias on the contact (22) of the hole injector may switch between a high and low voltage potential, between a high voltage potential and ground, or between a low voltage potential and ground. For a further increased hole current, an ohmic contact may be provided on the pGaN region (21), rather than a Schottky contact (22) as depicted in FIGS. 8 and 9. Other suitable contacts may also be used.

Over a period of operation, injected holes may accumulate in the GaN buffer region and prevent negative charge trapping in the GaN buffer region.

FIG. 10 illustrates a cross section schematic of another embodiment according to the present disclosure. The p-GaN region (23) and contact (24) act as the hole injector in a similar manner to p-GaN region (21) and contact (22) of FIG. 8. However, in FIG. 10, the p-GaN region (23) is formed directly on the GaN region (2). Advantageously, this may facilitate an increased hole current entering the GaN region (2), as the potential barrier for holes (when the hole injector terminal is at a positive potential compared to the potential at the surface of the GaN region (2)) is reduced compared to the embodiment shown in FIG. 8. The p-GaN region (23) may be formed on the GaN region (2) following a recessing of the AlGaN barrier layer in that region. In another example (not illustrated here), the AlGaN barrier may only be partially recessed, i.e. such that a thickness of the AlGaN barrier layer is reduced.

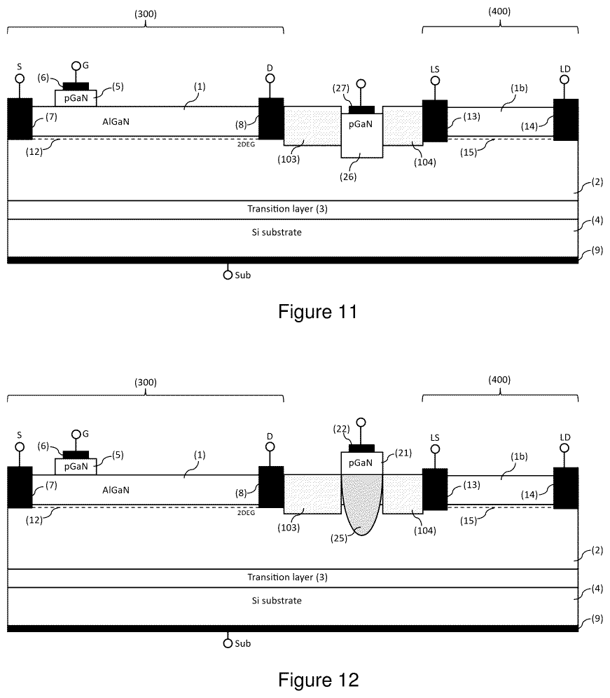

In another example schematically illustrated in FIG. 11, a section of the GaN region (2) may also be recessed before the p-GaN region (26) is formed. The p-GaN region (26) and contact (27) once again act as a hole injector, as described in previous embodiments. Advantageously, this may facilitate a further increased hole current entering the GaN region (2) compared to the embodiment of FIG. 10. The region where the GaN region (2) is recessed may be described as a trench in the GaN region (2).

FIG. 12 illustrates a cross section schematic of another embodiment according to the present disclosure. Many features of FIG. 12 correspond to those of FIG. 8. However, in FIG. 12 a p-doped region (25) is formed below the p-GaN region (21). The p-doped region (25) may be formed for example by the out-diffusion of dopants from the highly doped p-GaN region (21).

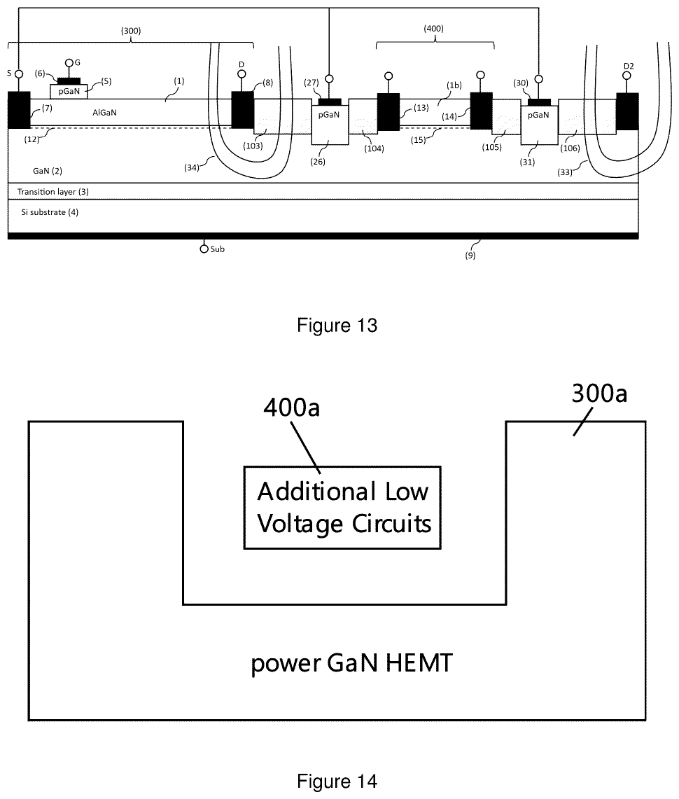

FIG. 13 illustrates a cross section schematic of another embodiment according to the present disclosure. In this embodiment two p-GaN regions (26, 31) are provided, both regions acting as hole injectors as previously described. The contacts (27, 30) on p-GaN region (26) and p-GaN region (31) are connected to the source terminal of the power HEMT (300). As described above, hole injection from the p-GaN regions (26, 31) may be more effective if they are biased at a positive potential (e.g. compared to the source terminal of the power HEMT). Nonetheless, the p-GaN regions (26, 31) of FIG. 13 may provide isolation of the low voltage components (400) in a power IC (for example a 2DEG resistor as illustrated) without the injection of holes, but rather through the shaping of the potential such that a high potential from the drain terminal during OFF-state operation of the power HEMT (300) does not reach the GaN buffer under the low voltage components (400). As previously discussed, FIG. 6 illustrates high voltage equipotential lines (32) during OFF-state operation of the power HEMT. In FIG. 6, high voltage equipotential lines reach the GaN buffer region under the 2DEG resistor (400). FIG. 13 meanwhile illustrates high voltage equipotential lines (33) and (34) during OFF-state operation of the power HEMT (300) with source-connected contacts (27), (30) of pGaN regions (26) and (31) respectively.

As shown in FIG. 13, high voltage equipotential lines do not reach the GaN buffer region under the 2DEG resistor (400). As such, a depletion region may be formed between the pGaN regions (26, 31) and the respective drain terminals adjacent to them, such that the potential applied to the drain terminal is dropped between the drain terminal and the respective adjacent pGaN regions.

The equipotential lines illustrated in FIG. 6 and FIG. 13 assume the substrate is connected to source potential. However, similar advantages may be provided in embodiments without a connection between the substrate and the source.

FIG. 14 illustrates a top view schematic of a power IC. FIG. 14 comprises a power GaN HEMT region (300a), and a second region (400a) where additional low voltage circuits may be formed on chip. The two regions are separated by an isolation region, for example region (100) as illustrated in FIG. 3.

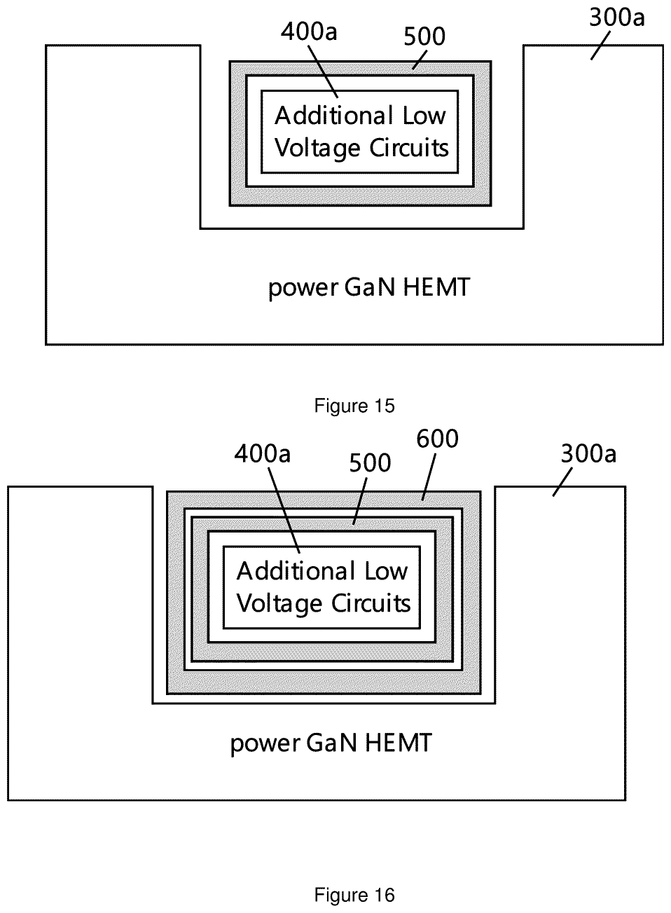

FIG. 15 illustrates a top view schematic of a power IC. the structure of FIG. 15 is similar to that depicted in FIG. 14 but additionally illustrates a shielding region (500) which surrounds the region (400a) for the additional low voltage circuits. The shielding region (500) may be formed as described for example in FIG. 4.

FIG. 16 illustrates a top view schematic of a power integrated circuit. FIG. 16 is similar to FIG. 15 but additionally illustrates a hole injector region (600) which surrounds the region (400a) for the additional low voltage circuits and the shielding region (500). The hole injector region (600) may be formed as described for example in FIG. 8, FIG. 10, FIG. 12.

Alternatively, the hole injector region (600) may be positioned between the shielding region (500) the region (400a) for the low voltage components.

In further implementations, more than one shielding region or hole injector region may be used, for example as depicted in FIG. 13. For example, hole injector region (600) may be formed between a first, inner, shielding region such as region (500) and a second, outer shielding region (not shown), and/or the shielding region (500) may be similarly positioned between first and second hole injector regions.

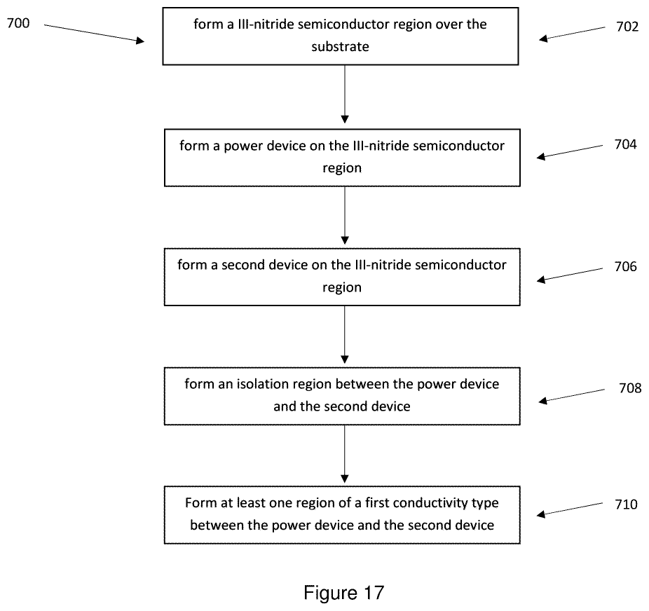

FIG. 17 depicts a flow diagram (700) of an example method of forming a AlGaN/GaN HEMT integrated circuit according to the present disclosure.

In step 702, an III-nitride semiconductor region over the substrate. The semiconductor region may comprise a GaN layer and an AlGaN layer. The layers may form a heterojunction at their interface, wherein the heterojunction comprises a 2DEG.

In step 704, a power device may be formed on the semiconductor region. Forming the power device may comprise forming a first terminal operatively connected to the III-nitride semiconductor region, a second terminal operatively connected to the III-nitride semiconductor region and laterally spaced from the first terminal, a gate structure located above the III-nitride semiconductor region and laterally spaced between the first and second terminals; and a control gate terminal operatively connected to the gate structure, wherein the control gate terminal is configured such that a potential applied to the control gate terminal modulates and controls a current flow through the two-dimensional carrier gas between the first and second terminals.

In step 706, a second (e.g. low voltage or additional) device may be formed on the semiconductor region.

In step 708, an isolation region may be formed between the power device and the second device. The isolation region may be formed such that it separates the 2DEG in the power device and the second device into two distinct regions of 2DEG, for example by removal of the AlGaN barrier layer.

In step 710, at least one region of a first conductivity type if formed between the active area of power device and the active area of the second device. For example, the region may be formed in the isolation region.

It will be understood that the steps depicted in method (700) are provided for example only, and are not intended to limit the scope of the present disclosure. For example, the steps 702-710 may occur in different orders, and/or some steps may be combined to form a single process step. For example, a highly p doped GaN region which forms the injector of carriers and a highly p doped GaN region which forms the gate structure of the power device may be formed in the same process step. Similarly, a metal contact which forms the control terminal and the metal contact formed on the injector of carriers may also be formed in the same process step.

### LIST OF REFERENCE NUMERALS

1—AlGaN layer;

1b—AlGaN layer;

1c—AlGaN layer;

2—GaN layer;

3—transition layer;

4—substrate;

5—pGaN region;

6—gate contact;

7—source contact;

8—drain contact;

9—back metallisation contact;

10—metal field plate structure;

11—dielectric region;

12—2DEG;

13—2DEG resistor first contact;

14—2DEG resistor second contact;

15—2DEG;

18—negative trapped charges;

19—negative trapped charges;

20—contact;

21—pGaN region;

22—contact;

23—pGaN region;

24—contact;

25—p-doped region;

26—pGaN region;

27—contact;

28—resistor

29—resistor

30—contact;

31—pGaN region;

32—voltage equipotential lines;

33—voltage equipotential lines;

34—voltage equipotential lines;

35—hole current

100—isolation region;

101—isolation region;

102—isolation region;

103—isolation region;

104—isolation region;

105—isolation region;

106—isolation region;

300—power HEMT;

300a—power HEMT;

400—low voltage component;

400a—low voltage component;

500—shielding region;

600—hole injector region;

700—flow diagram;

702—method step;

704—method step;

706—method step;

708—method step;

710—method step.

The skilled person will understand that in the preceding description and appended claims, positional terms such as ‘top’, ‘above’, ‘under’, ‘lateral’, etc. are made with reference to conceptual illustrations of a device, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

Many other effective alternatives will occur to the person skilled in the art. It will be understood that the disclosure is not limited to the described embodiments, but encompasses all the modifications which fall within the spirit and scope of the disclosure.

1. A III-nitride semiconductor based heterojunction integrated circuit (IC), comprising:
a substrate;
a III-nitride semiconductor region located over the substrate, wherein the III-nitride semiconductor region comprises a heterojunction comprising at least one two-dimensional carrier gas of a second conductivity type;
a power device comprising:
a first terminal operatively connected to the III-nitride semiconductor region;
a second terminal operatively connected to the III-nitride semiconductor region and laterally spaced from the first terminal;
a gate structure located above the III-nitride semiconductor region and laterally spaced between the first and second terminals; and
a control gate terminal operatively connected to the gate structure, wherein the control gate terminal is configured such that a potential applied to the control gate terminal modulates and controls a current flow through the two-dimensional carrier gas between the first and second terminals;
a second device comprising at least one second two-dimensional carrier gas of the second conductivity type;
an isolation region between the power device and the second device such that the two dimensional carrier gas of the power device and the second two dimensional carrier gas of the second device are separated by the isolation region to form two distinctive active areas of two dimensional carrier gas; and
at least one region of a first conductivity type positioned laterally between an active area of the power device and an active area of the second device, wherein a Schottky or ohmic metal contact is formed on the at least one region of the first conductivity type.

2. The heterojunction IC of claim 1, wherein the at least one region of the first conductivity type is located within the isolation region.

3. The heterojunction IC of claim 1, wherein the at least one region of the first conductivity type is a carrier injector configured to inject carriers of the first conductivity type into the III-nitride semiconductor region.

4. The heterojunction IC of claim 3, wherein the carrier injector laterally surrounds the second device.

5. The heterojunction IC of claim 3, wherein the carriers of the first conductivity type are holes.

6. The heterojunction IC of claim 1, comprising a terminal operatively connected to the Schottky or ohmic metal contact is formed on the at least one region of the first conductivity type, wherein the terminal is biased at a ground potential.

7. The heterojunction IC of claim 1, comprising a terminal operatively connected to the Schottky or ohmic metal contact is formed on the at least one region of the first conductivity type, wherein the terminal is biased at a fixed positive bias.

8. The heterojunction IC of claim 7, wherein either:
(i) the terminal is biased at the fixed positive bias by a DC rail; or
(ii) the heterojunction IC comprises a potential divider configured to bias the terminal at a fraction of the DC rail.

9. The heterojunction IC of claim 1, comprising a terminal operatively connected to the Schottky or ohmic metal contact is formed on the at least one region of the first conductivity type, wherein the terminal is biased at a switching potential between a ground potential and a fixed positive bias, and wherein the terminal is biased at the switching potential by one of (i) the power device control signal; (ii) the drain potential of the power device; or (iii) a fraction of the drain potential of the power device via a potential divider.

10. The heterojunction IC of claim 1, wherein the III-nitride semiconductor region comprises an AlGaN barrier layer and a GaN layer, and wherein the heterojunction is formed at a junction between the AlGaN barrier layer and the GaN layer, and wherein the GaN layer comprises a GaN buffer region and a GaN channel region.

11. The heterojunction IC of claim 10, wherein the GaN buffer region is highly doped and the GaN channel region is unintentionally doped.

12. The heterojunction IC of claim 11, wherein the GaN buffer region is carbon doped.

13. The heterojunction IC of claim 3, wherein either:
(i) the carrier injector is formed on a GaN layer of the III-nitride semiconductor region; or
(ii) the carrier injector is formed in a trench in a GaN layer of the III-nitride semiconductor region.

14. The heterojunction IC of claim 3, wherein the carrier injector is a region of highly p doped GaN, and wherein the carrier injector is formed on a AlGaN barrier layer of the III-nitride semiconductor region.

15. The heterojunction IC of claim 14, wherein the AlGaN barrier layer is partially recessed.

16. The heterojunction IC of claim 1, wherein the gate structure comprises a region of highly p doped GaN formed on a AlGaN barrier layer of the III-nitride semiconductor region, and wherein the control gate terminal is a Schottky or Ohmic metal contact formed on the highly p doped GaN.

17. The heterojunction IC of claim 1, wherein either:
(i) the isolation region does not comprise the heterojunction comprising the at least one two-dimensional carrier gas of a second conductivity type; or
(ii) the isolation region comprises a region of ion implantation, wherein the region is configured to reduce the conductivity of the at least one two-dimensional carrier gas by a factor of at least 100.

18. The heterojunction IC of claim 1, wherein the second device comprises one or more of:
an enhancement mode transistor;
a depletion mode transistor;
a capacitor;
a resistor; or
a diode.

19. The heterojunction IC of claim 1, wherein the isolation region comprises at least one shielding region, wherein the shielding region comprises an ohmic contact; and wherein the shielding region is biased at one of (i) a ground potential; (ii) a fixed bias; or (iii) a switching potential between a ground potential and a fixed bias.

20. A method of forming an III-nitride semiconductor based heterojunction integrated circuit (IC), comprising:
forming a substrate;
forming a III-nitride semiconductor region over the substrate, wherein the III-nitride semiconductor region comprises a heterojunction comprising at least one two-dimensional carrier gas of a second conductivity type;
forming a power device on the III-nitride semiconductor region, the power device comprising:
a first terminal operatively connected to the III-nitride semiconductor region;
a second terminal operatively connected to the III-nitride semiconductor region and laterally spaced from the first terminal;
a gate structure located above the III-nitride semiconductor region and laterally spaced between the first and second terminals; and
a control gate terminal operatively connected to the gate structure, wherein the control gate terminal is configured such that a potential applied to the control gate terminal modulates and controls a current flow through the two-dimensional carrier gas between the first and second terminals;
forming a second device on the III-nitride semiconductor region, the second device comprising at least one second two-dimensional carrier gas of the second conductivity type;
forming an isolation region between the power device and the second device such that the two dimensional carrier gas of the power device and the second two dimensional carrier gas of the second device are separated by the isolation region to form two distinctive active areas of two dimensional carrier gas;
forming at least one region of a first conductivity type positioned laterally between an active area of the power device and an active area of the second device; and
forming a Schottky or ohmic metal contact on the at least one region of the first conductivity type.
